(19) United States
(12) Patent Application Publication
(10) Pub. No.: US 2020/0305312 A1
(43) Pub. Date: Sep. 24, 2020

(54) MINIATURIZED CLOSED-LOOP COOLING SYSTEM

(71) Applicant: Ice Qube, Inc., Geensburg, PA (US)

(72) Inventors: Jeffrey Scott Palmer, Greensburg, PA (US); Justin Greubel, Greensburg, PA (US); Jamshaid Ullah, Shenzhen (CN)

(73) Assignee: Ice Qube, Inc., Greensburg, PA (US)

(21) Appl. No.: 16/840,323

(22) Filed: Apr. 3, 2020

Related U.S. Application Data
(63) Continuation of application No. PCT/US2018/053072, filed on Sep. 27, 2018.
(60) Provisional application No. 62/568,564, filed on Oct. 5, 2017.

(51) Int. Cl. H05K 7/20

(52) U.S. Cl. CPC H05K 7/20818; H05K 7/20309; H05K 7/20318; H05K 7/20327; H05K 7/20736; H05K 7/20172

(57) ABSTRACT

An embodiment provides for cooling of a server rack enclosure. In one example, an evaporator includes: an evaporator housing having: a first surface having a first end that includes a warm air inlet that conducts warm air from inside a server rack enclosure and second end that includes a cool air outlet that returns cooled air to the server rack enclosure; evaporator coils positioned between the warm air inlet and the cool air outlet that cool the warm air from the inside of the server rack enclosure; and an airflow generating unit that provides airflow between the warm air inlet and the cool air outlet, the airflow transiting about the evaporator coils. The evaporator coils include tubing positioned in a connection port of the evaporator housing. The tubing is configured to attach to a remote condenser unit. Other embodiments are described and claimed.

### CROSS-REFERENCE TO RELATED APPLICATIONS

This application is a continuation of international patent application number PCT/US18/53072, filed Sep. 27, 2018, which claims the benefit of U.S. Provisional Patent Application Ser. No. 62/568,564, filed on Oct. 5, 2017, the contents of these prior applications are incorporated by reference in their entirety herein.

### FIELD

The subject matter described herein generally relates to closed-loop cooling systems. Certain subject matter described herein relates to closed-loop cooling of small enclosures or room(s). Certain subject matter described herein relates to closed-loop cooling of server rack enclosures.

### BACKGROUND

Small rooms or enclosures, such as a server room, closet, or a server rack enclosure or cabinet, are conventionally provided with a packaged air conditioning unit for cooling the ambient air of the room or the enclosure. The air conditioning units are packaged in that the air conditioning units have both a condenser and an evaporator portion in the same housing. These packaged air conditioning units operate like standard air conditioners and help keep the contents of the room or the enclosure, e.g., servers, cool by cooling the ambient air of the room or the enclosure.

### BRIEF SUMMARY

One embodiment provides an evaporator for cooling a server rack enclosure, comprising: an evaporator housing comprising: a first surface having a first end that includes a warm air inlet that conducts warm air from inside a server rack enclosure and second end that includes a cool air outlet that returns cooled air to the server rack enclosure; evaporator coils positioned between the warm air inlet and the cool air outlet that cool the warm air from the inside of the server rack enclosure; and an airflow generating unit that provides airflow between the warm air inlet and the cool air outlet, the airflow transiting about the evaporator coils; the evaporator coils including tubing positioned in a connection port of the evaporator housing; the tubing being configured to attach to a remote condenser unit.

Another embodiment provides a system for cooling a server rack enclosure, comprising: a housing comprising: a first surface having a first end that includes a warm air inlet that conducts warm air from inside a server rack enclosure and second end that includes a cool air outlet that returns cooled air to the server rack enclosure; evaporator coils positioned between the warm air inlet and the cool air outlet that cool the warm air from the inside of the server rack enclosure; and an airflow generating unit that provides airflow between the warm air inlet and the cool air outlet, the airflow transiting about the evaporator coils; and a mounting mechanism for mounting the housing at a position within the server rack enclosure selected from the group consisting of a bottom mount position, a middle mount position, and a top mount position; wherein the mounting mechanism comprises a bracket that reversibly attaches to server rails within the server rack enclosure housing.

A further embodiment provides a system comprising: a server rack enclosure; a server rack comprising a plurality of rails; and an evaporator housing comprising: a first surface having a first end that includes a warm air inlet that conducts warm air from inside a server rack enclosure and second end that includes a cool air outlet that returns cooled air to the server rack enclosure; evaporator coils positioned between the warm air inlet and the cool air outlet that cool the warm air from the inside of the server rack enclosure; and an airflow generating unit that provides airflow between the warm air inlet and the cool air outlet, the airflow transiting about the evaporator coils; the evaporator coils including tubing positioned in a connection port of the evaporator housing; the tubing being configured to attach to a remote condenser unit.

The foregoing is a summary and thus may contain simplifications, generalizations, and omissions of detail; consequently, those skilled in the art will appreciate that the summary is illustrative only and is not intended to be in any way limiting.

For a better understanding of the claimed embodiments, reference is made to the following description and the accompanying drawings.

### BRIEF DESCRIPTION OF THE SEVERAL VIEWS OF THE DRAWINGS

FIG. 1 illustrates an example server rack cooling system according to an embodiment.

FIG. 2 illustrates a perspective view of an example evaporator according to an embodiment.

FIG. 3 illustrates a top view of the evaporator of FIG. 2 without a plate.

FIG. 4 illustrates a perspective view of an example condenser according to an embodiment.

FIG. 5 illustrates an example server rack cooling system according to an embodiment.

FIG. 6 illustrates an example server rack cooling system according to an embodiment.

FIG. 7 illustrates an example server rack cooling system according to an embodiment.

FIG. 8 illustrates an example evaporator according to an embodiment.

FIG. 9 illustrates a top view of the evaporator of FIG. 8.

FIG. 10 illustrates an example evaporator mounted in a server rack according to an embodiment.

FIG. 11 illustrates a perspective view of an example evaporator mounted in a server rack according to an embodiment.

### DETAILED DESCRIPTION

It will be readily understood that the components of the embodiments, as generally described and illustrated in the figures herein, may be arranged and designed in a wide variety of different configurations in addition to the described example embodiments. Thus, the following more detailed description of the example embodiments, as represented in the figures, is not intended to limit the scope of the claims but is merely representative of those embodiments.

Reference throughout this specification to “embodiment(s)” (or the like) means that a feature, structure, or characteristic described in connection with the embodiment is included in at least one embodiment, which may or may not be claimed. Thus, appearances of the phrases “according to embodiments” or “an embodiment” (or the like) in various places throughout this specification are not necessarily all referring to the same embodiment.

Furthermore, the described features, structures, or characteristics may be combined in any suitable manner in one or more embodiments. In the following description, numerous specific details are provided to give a thorough understanding of example embodiments. One skilled in the relevant art will recognize, however, that aspects can be practiced without one or more of the specific details, or with other methods, components, materials, etc. In other instances, well-known structures, materials, or operations are not shown or described in detail to avoid obfuscation.

In small enclosures such as a server rack enclosure, packaged air conditioning units are conventionally used. Servers are conventionally placed in an enclosure by mounting or placing them on racks within the enclosure or cabinet. When the servers are running, a large amount of heat is generated. Server housings include an internal fan for air circulation, conducting air through the server housing or case, often from front to back. Therefore, servers mounted on rails within an enclosure pull air from the front of the enclosure (cold aisle) and expel heated air to the rear of the enclosure (hot aisle).

Packaged air conditioning units recirculate the air within the server enclosure, or if vented to ambient air, within the server room. This recirculation gradually raises the temperature within the enclosure or the room.

A conventional implementation technique for packaged air conditioning units is to mount them on the top or side of the server rack enclosure. Side mounted air conditioning units are mounted to the side of the rack enclosure (e.g., the side wall of the enclosure or cabinet) and include a supply (cold air in) and a return (warm air out). The air-in and air-out locations of side mounted air conditioning units generally do not provide a flow of air that matches the required flow of air for a server itself, because servers generally include fans that pull air from the front of the rack to the rear.

The servers thus would benefit from conditioned air provided in the front aisle (cold aisle) of the server rack, as this is the air that is pulled in through the fan within the server housing. The heated air is discharged out of the back of the server housing (i.e., opposite the front of the server) through the rear of the rack enclosure, i.e., the hot aisle. In a conventional side mount configuration, the packaged air conditioning unit is not designed to pull warm air efficiently from the hot aisle of the server rack enclosure, nor is it typically configured to deliver cool air to the front of the servers within the rack. Therefore, a conventional packaged air conditioning unit is not an effective or efficient for cooling a server rack enclosure.

Another problem with conventional air conditioning units that are mounted on the side of a server rack enclosure is that they do not account for configurations in which the racks or rack enclosures are mounted side-by-side, e.g., with their enclosures (cases or shells) or rails bolted or placed close together. Using a conventional side mounted air conditioning unit, where an air conditioner is effectively hanging on the side of the server rack enclosure, is generally prohibited for side-by-side rack enclosures.

Accordingly, an embodiment provides for an air conditioning system for effectively and efficiently cooling server rack enclosures.

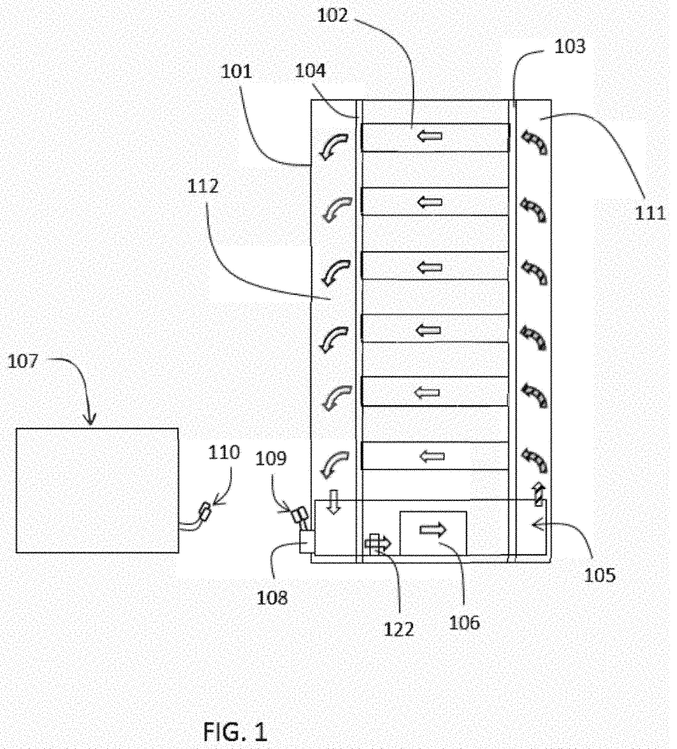

Referring to FIG. 1, a side view is illustrated of an embodiment that includes two primary components or parts, namely, an evaporator part 105 and a condenser part 107, which are provided in a split configuration. The evaporator part 105 comprises an assembly of coils 106 that contain a coolant. The evaporator part 105 operates by evaporating the coolant to generate a chilled coolant for cooling the air that is circulated about the coils 106, e.g., by operation of a fan or impeller 122. The condenser part 107 includes a condenser coil and regenerates the coolant, and is in fluid communication with the evaporator part via tubing 110 of the condenser part 107 and the tubing 109 of the evaporator part 105.

In an embodiment, the evaporator part 105, which is the cooling portion, is split or separated from the condenser part 107, which is the heat rejection portion. In an embodiment, the evaporator part 105 and the condenser part 107 are physically separated by placing the evaporator part 105 within the server rack enclosure 101 and placing the condenser part 107 outside of the server rack enclosure 101, e.g., within the server room or outside the server room (such as in another room or outside of the building). In contrast to conventionally known evaporators and condensers of packaged air conditioning units, which are housed within the same housing or case, an embodiment provides for separate evaporator part 105 and condenser part 107.

In the example shown in FIG. 1, the evaporator part 105 is mounted within the server rack enclosure 101 on the bottom. While an embodiment is described in a split configuration, that is where the enclosure part 105 and the condenser part 107 are provided in separate, modular units, this is not necessarily required. For example, an embodiment may be provided as a packaged unit, namely, one in which the evaporator and the condenser are located within the same housing.

With continued reference to FIG. 1, the evaporator part 105 may be mounted on the rails 103, 104 of the server rack enclosure 101, similar to the mounting of a server, one of which is labeled at 102. As shown, the front of the server rack enclosure 101 of FIG. 1 is to the right, and the server(s) 102 pull cooled air (indicated by striped arrows) into the front of the casing of the server 102. This cooled air is used to cool the server 102 and warmed air (indicated by non-striped arrows) is expelled from the back of the server 102.

In the embodiment illustrated in FIG. 1, the evaporator part 105 includes one or more warm air intakes and one or more cold air outlets, as further described herein. These are positioned on the evaporator part 105 to provide cool air to the front of the server rack enclosure 101 and take up warm air from the back of the server rack enclosure 101, setting up the cold aisle 111 and the hot aisle 112 that is optimal for the air flow of the server node(s) 102. In an embodiment, the cold aisle 111 and the hot aisle 112 may be about 6 inches to about 8 inches in depth.

The air of the server rack enclosure 101 remains in a stable, cool condition with the assistance of the remotely located condenser part 107, which may be connected to the evaporator part 105 via tubing 109, 110 of each. In the example of FIG. 1, the tubing 109 exits the back of the evaporator part 105 and is provided to a connection port or area 108. The connection port 108 may transit through the lower rear of the server rack enclosure 101, or the tubing 109 may do so alone, with appropriate sealing provided to maintain the closed-loop air circulation within the server rack enclosure 101. This allows heat to be carried via tubing 109, 110 to the condenser part 107, and out of the server enclosure or even out of the server room, e.g., to another room or outside of the building, where it is cooled with a larger pool of ambient air.

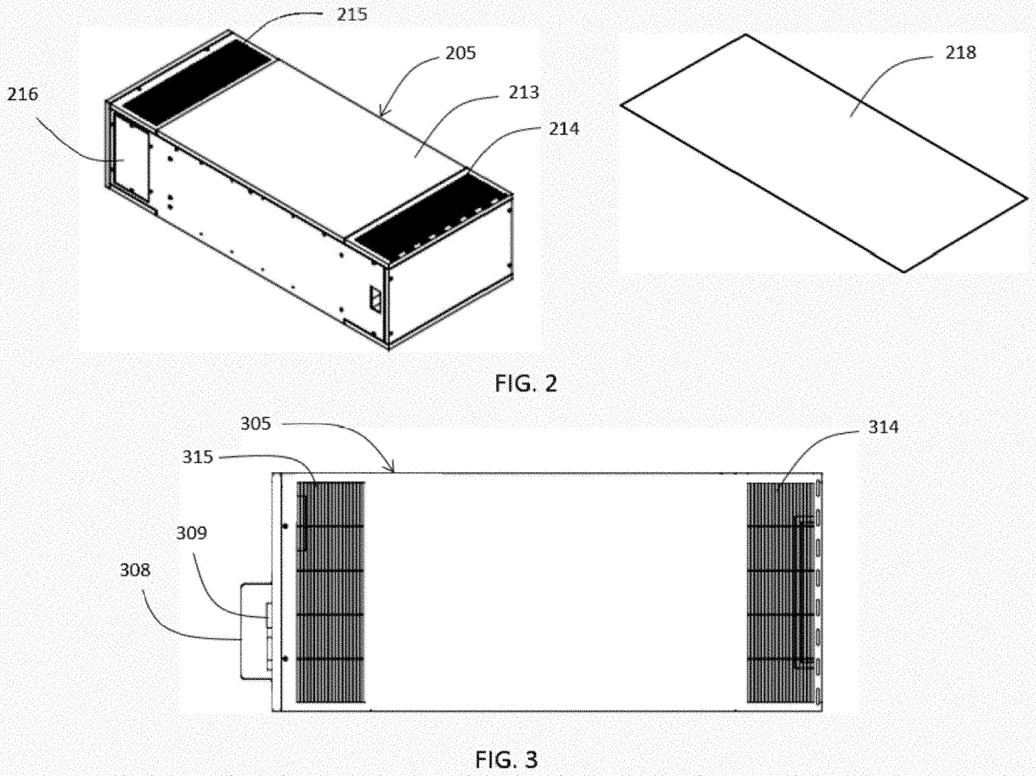

FIG. 2 and FIG. 3 illustrate a perspective view and a top view of an example evaporator part according to an embodiment. Referring to FIG. 2, the evaporator part 205 includes a housing with a surface 213 (in this example, the upper surface). The surface 213 comprises a cool air outlet 214 and a warm air inlet 215. The cool air outlet 214 provides cool air to the cold aisle of the server rack enclosure, e.g., when mounted as illustrated in FIG. 1. Similarly, the warm air inlet 215 accepts warm return air from the hot aisle. An optional digital controller 216 may be mounted to a side surface (or elsewhere, as further described herein). The controller contains circuitry designed to regulate the operation of the evaporator part 205 and component parts thereof, e.g., perform the functions of a thermostat, a fan controller, etc.

The surface 213 illustrated in FIG. 2 may be the top surface of the evaporator part 205, the bottom surface of the evaporator part 205, or both. That is, the surface 213 may be replicated (or substantially replicated) to provide the bottom surface of the evaporator part 205 with similar air inlet(s) and outlet(s). For example, an embodiment includes a total of four openings, i.e., two cold air outlets and two warm air inlets positioned at the top and bottom of the evaporator part 205. A plate or plate(s) 218, which may be formed in multiple parts, may be provided and attached to the surface 213 to block the air flow from exiting and entering the cool air outlet 214 and the warm air inlet 215, respectively. The plate 218 may be used, for example, to block air flow for a top mounted (interior or exterior) or bottom mounted (interior or exterior) configuration, restricting air flow to only one side of the evaporator part 105, as further described herein.

FIG. 3 provides a top view of the example evaporator part 305 of FIG. 2. The cool air outlet 314 and warm air inlet 315 are illustrated in relation to the front and rear of the evaporator part 305. In the view illustrated in FIG. 3, the connection port 308 and tubing 309 are positioned at the rear of the evaporator part 305.

In an embodiment, the evaporator part illustrated in FIG. 1, FIG. 2 and FIG. 3 may be provided in a variety of dimensions. For example, an embodiment provides a cooling system that provides between about 3 KW-10 KW (10230-34100 Btu/h or 2998-9994 Watts) of cooling capacity. In one embodiment, the evaporator part 305 includes a housing that is about 10.45 inches (266 mm) in height, about 17.32 inches (440 mm) in width, and about 40.00 inches (1016 mm) in depth. In another embodiment, the evaporator part 305 includes a housing that is about 14.02 inches (356 mm) in height, about 17.32 inches (440 mm) in width, and about 45.00 inches (1143 mm) in depth. In another embodiment, the evaporator part 305 includes a housing that is about 15.79 inches (401 mm) in height, about 17.32 inches (440 mm) in width, and about 45.00 inches (1143 mm) in depth.

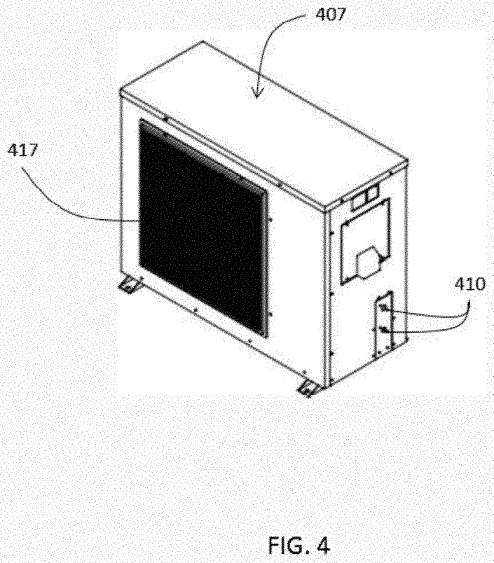

Illustrated in FIG. 4 is a condenser part 407. The condenser part 407 includes a fan intake 417 that provides air cooling to fluid returned from the evaporator part via tubing 410. In one embodiment, the condenser part 407 includes a housing that is about 23.61 inches (600 mm) in height, about 29.69 inches (754 mm) in width, and about 11.97 inches (304mm) in depth. In another embodiment, the condenser part 407 includes a housing that is about 43.27 inches (1099 mm) in height, about 29.69 inches (754 mm) in width, and about 13.94 inches (35 4mm) in depth. In another embodiment, the condenser part 407 includes a housing that is about 46.02 inches (1169 mm) in height, about 35.59 inches (904 mm) in width, and about 13.94 inches (354 mm) in depth. In a further embodiment, the condenser part 407 includes a housing that is about 46.02 inches (1169 mm) in height, about 43.47 inches (1104 mm) in width, and about 13.94 inches (354 mm) in depth. As illustrated, the condenser part may include feet, e.g., proximate to each corner. In an embodiment, the feet are provided with an attachment mechanism, e.g., threaded holes, for attaching or mounting to various surfaces, e.g., mounting onto a wall or platform.

In an embodiment, the evaporator part 305 is designed to fit between 19-inch (482.6 mm) server rack rails. This permits the evaporator part 305 to be placed within a server rack enclosure, e.g., similar to a server, as described herein. Further, the evaporator part 305 and condenser part 407 can be configured to operate using 120 Volts/60 Hz power or 230 Volts/60 Hz power.

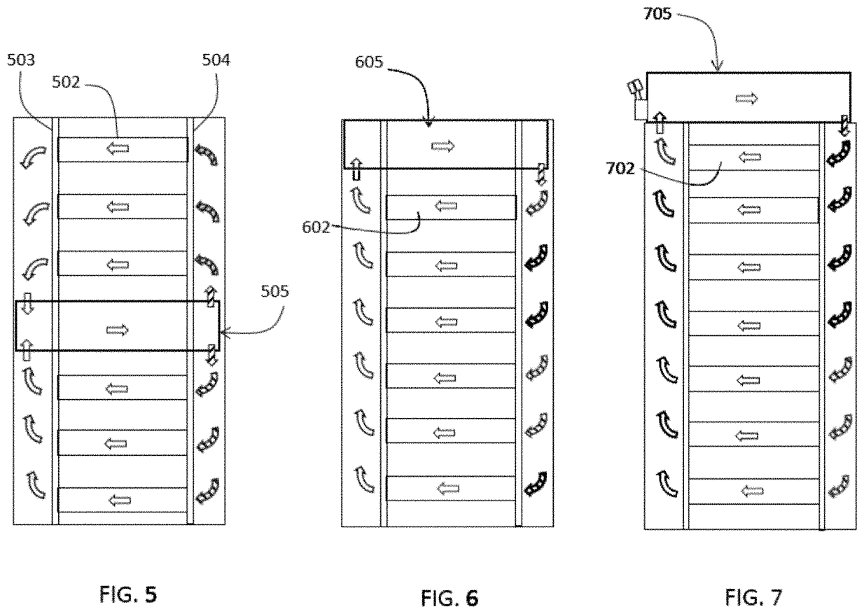

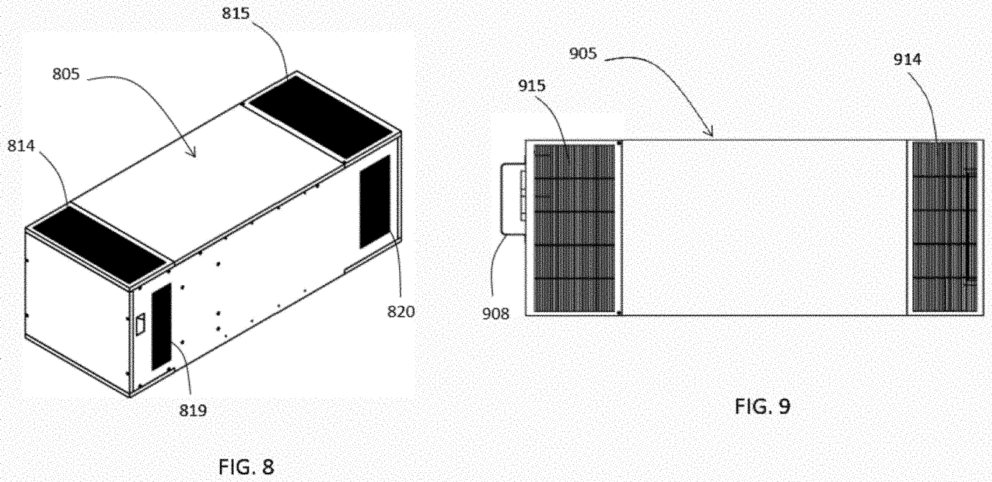

Referring to FIG. 5, FIG. 6, and FIG. 7, the evaporator part 505, 605, and 705, respectively, is repositionable. For example, the server rack cooling system (either the evaporator part alone, or a packed unit containing both an evaporator part and a condenser part) may be located in a bottom mount configuration (illustrated in FIG. 1), a middle mount configuration (illustrated in FIG. 5), a top mount configuration (illustrated in FIG. 6), or an external (e.g., top) mount configuration (illustrated in FIG. 7). More than one cooling system may be provided within the server rack enclosure, e.g., two or more evaporator parts may be provided within the same server rack enclosure. Further, one or more cooling systems may be located within a server rack enclosure, and/or a server rack cooling system may be located on top of the server rack enclosure. In some configurations, air inlets and outlets may be covered or omitted to appropriately redirect the airflow within the server rack enclosure to ensure closed-loop operation, as further described herein. Further, some embodiment provides evaporator part housings or packaged unit housings that include additional air inlet(s) and/or outlet(s), as further described by way of example in connection with FIG. 8 and FIG. 9.

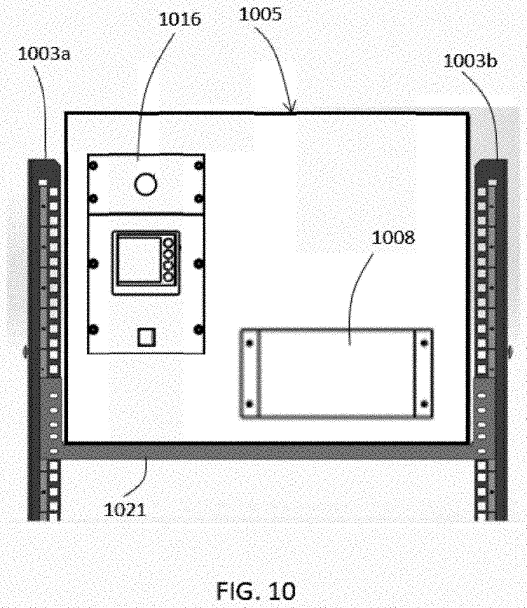

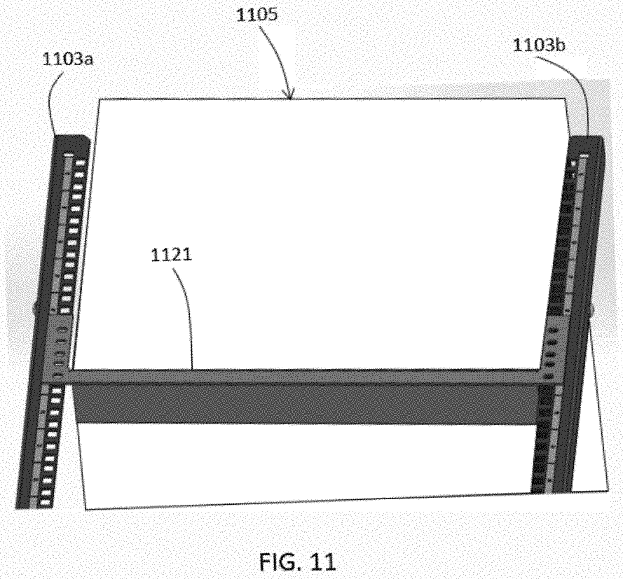

In the example of FIG. 5, an evaporator part 505 is illustrated in a middle mount position, where servers (one of which is indicated at 502) are positioned above and below the evaporator part 505. The front and rear rack rails 503, 504 secure the server(s) 502 and evaporator part 505 in place. In this configuration, the evaporator part 505 is mounted in the mid-section of the rack. An internal mounting bracket (illustrated in FIG. 10 and FIG. 11) may be installed and secured to the rails 503, 504 at the height desired. Further, the evaporator part 505 may include a plurality of intakes and outlets, which may be exposed by removing the plate 218. The evaporator part 505 will then supply cool air (indicated by the striped arrows) to the cold aisle above and below. The heated air (indicated by the non-striped arrows) being discharged by the servers 502 will return from the rear to the evaporator part 505 from above and below. Heated air will be re-cooled and sent back to the cold aisle. This middle mount configuration keeps cold air closer to all servers 502.

Illustrated in FIG. 6 is a top (internal) mount configuration for the evaporator part 605. In this configuration, the evaporator part 305 is mounted inside the enclosure at the top. Cold air (indicated by the striped arrows) flows down the front cold aisle and warm air (indicated by the non-striped arrows) from the rear flows up into the return air inlet of the evaporator part 605. This configuration can use as little as 6 RU (rack units) of space inside the rack. As in the exterior top mount application, illustrated in FIG. 7, the warm air inlet and cool air outlet on the bottom of the evaporator part 605 may be exposed by removing or omitting the blank plate(s) 218 on the bottom of the evaporator part. Likewise, top surface air inlet(s) and outlet(s) of the evaporator part 605 may be omitted or covered with plate(s). In this top (internal) mount configuration, an internal (rack) mounting bracket is used.

Referring now to FIG. 7, the evaporator part 705 can be mounted on the exterior top of the rack enclosure. By covering or omitting the air inlet and air outlet on top of the evaporator part 705, e.g., placing the blank plate(s) 218 on the top surface of the evaporator part 705, cold air (indicated by the striped arrows) will be directed to flow down the cold aisle and warm air (indicated by the non-striped arrows) will be directed to flow up from the rear of the server rack enclosure into the warm air inlet of the evaporator part 705, where it is re-cooled and sent back to the cold aisle. Top exterior mounting brackets are optional and cut outs will be required in the top side of the enclosure to permit air flow. As with other configurations in which the server rack enclosure is to be breached (e.g., for accommodating the connection port 108 and/or tubing 109, 110), a gasket kit and mounting hardware may be included for this type of mounting. An exterior mounting configuration does not use any rack space.

An embodiment provides an evaporator part that includes additional air inlet(s) and/or air outlet(s), e.g., for accommodating different server rack enclosure configurations. For example, as illustrated in FIG. 8, an evaporator part 805 includes a cool air outlet 814 and a warm air inlet 815 on the top surface, and may also include similar air inlets and outlets on the bottom surface in a symmetrical manner. Additionally, the evaporator part 805 may include one or more side air inlet(s) and/or one or more side air outlet(s). As illustrated in the example of FIG. 8, the evaporator part 805 includes a side cool air outlet 819 and a side warm air inlet 820. The opposite surface of the evaporator part may likewise contain side air inlet(s) and/or side air outlet(s).

An evaporator part 805 such as that illustrated in the example of FIG. 8 may be used in a multi-rack configuration where more than one set of rack rails are attached together in a larger server rack enclosure and/or one or more server rack enclosures are attached together with interior sidewalls removed. This permits the evaporator part 805 to be centrally located, e.g., using a mid-rack mounting configuration, and to provide cooling air above, below and to each side. The evaporator part 805 may likewise collect returned warm air in each of these directions using top, bottom and side warm air inlets.

FIG. 9 illustrates the evaporator part 805 of FIG. 8 in a top view. Here it can be appreciated that the cold air outlet 914 is positioned near the front of the evaporator part 905, whereas the warm air inlet 915 is positioned nearer the rear of the evaporator part 905, proximate to the side including the connection port 908.

Illustrated in FIG. 10 is a back view of a set of rack rails 1003a, 1003b (corresponding to left and right rails of the front rail 103 in FIG. 1). The rails 1003a, 1003b may be separated, for example, by about 19 inches. In addition, the back of an example evaporator part 1005 is visible. Here, the evaporator part 1005 has been situated on top of a mounting bracket 1021, which is in turn attached to the rails 1003a, 1003b, e.g., via threaded screws or bolts. The mounting bracket 1021 may be repositioned on the rails 1003a, 1003b, for example by moving an attachment mechanism such as repositioning threaded bolts or screws into different holes within the rails 1003a, 1003b. This permits the evaporator part 1005 to be mounted anywhere within the server rack enclosure that provides enough space for the evaporator part 1005.

Also illustrated in FIG. 10 is a controller 1016, which in this example is located on the back face of the evaporator part 1005, proximate to the connection port 1008. The controller 1016 may be located in a variety of different locations, e.g., on the front face and/or on the side face of the evaporator part 1005. This may facilitate easy manual access to the controller 1016.

FIG. 11 provides a (lower) perspective view of an example mounting bracket 1121. In this example, the mounting bracket 1121 is about 1-2 inches in depth and acts in conjunction with a front mounting bracket (not illustrated) to support the evaporator part 1105 mounted thereon. Thus, the evaporator part 1105 may be mounted on the server rack rails 1103a, 1103b to provide cooling to the server rack enclosure.

In each of the example embodiments described, the air inlet(s) and/or the air outlet(s) of the evaporator part or a packed air conditioning unit may be supplied with grills. The grills may be removable, e.g., when a cover plate such as plate 218 is required or desirable given the location of the evaporator part or packaged air conditioning unit.

In order to control moisture in any humid air of the server rack enclosure, any of the evaporator parts and/or packaged air conditioning units described herein may include a condensation management system, e.g., to manage condensation that is accumulated as a result of operating the evaporator coils of the evaporator part. For example, a drain pain or like element may be placed proximate to, e.g., below, the evaporator coils in order to facilitate capture of any condensation that may accumulate and fall. Further, a drain pan or like element may include a mechanism that permits controlled removal of accumulated condensation, e.g., using tubing or drainage system. Further, a drain pan or like element may include an alarm, which responds to a predetermined level or the presence of accumulated condensation and/or moisture. The alarm may trip an indication mechanism, e.g., provide an indication on a controller such as controller 1016, provide an indication to a remote device such as a smart phone or dedicated remote control in operative communication with a controller such as controller 1016, or a combination of the foregoing.

The embodiments described herein include, but are not limited to, cooling units that can be implemented for cooling server rack enclosures or small rooms, containers, or closets, without risk of overheating the enclosure, small room, or closet, or causing runaway conditions with heat. The noise of certain embodiments is significantly less than that of a traditional packaged air conditioner unit since in certain embodiments, the condenser part, which is where the compressor is located, is located remote from the evaporator part, e.g., the condenser part can be placed outside or in another area insulated from noise.

The embodiments described herein provide a higher cooling efficiency than conventional air conditioning units, particular conventional packaged air conditioning units, by creating a lower temperature surrounding the rack enclosure via the remote condenser part.

Further, the embodiments also provide more effective and efficient cooling due to the hot and cold aisle system being facilitated by virtue of the mounting locations for the evaporator part and/or the locations of the air inlet(s) and/or air outlet(s). In operation, variable speed air flow provided by an embodiment, e.g., as programmed into a controller of an evaporator part, is believed to be more efficient and result in lower power consumption during low load requirements, such as when servers are not running. Because the evaporator part can be positioned at various points along the server rack, this allows for more cooling options and more even and adequate cooling inside the entire area of the server rack enclosure or other enclosure.

It will be noticed as well that less space is required, e.g., in a server room, because in various embodiments the condenser part can be located outside the enclosure or even outside of the room or building. Also, because a packaged air conditioner is not mounted on the side of the rack enclosure, rack enclosures can be bolted together and be made more compact. As described above, in some embodiments there can be more than one evaporator part for each condenser part and vice versa. This for example allows for a higher concentration of cooling in a smaller space.

A condensation pump located in the evaporator part can be used to remove water developed by the evaporator coils. As the condensation level rises, the pump removes the condensate to an alternate location. An alarm device can be located in the bottom of the evaporator portion to detect water in the event the condensate pump fails or becomes inadequate.

For embodiments that include a packaged unit having both an evaporator part and a condenser part in the same physical housing, these embodiments can be installed inside the server rack enclosure for space savings while maintaining the cold aisle and hot aisle air flows on the evaporator side of the air conditioner.

Example embodiments are described herein with reference to the figures, which illustrate example methods, devices and products according to various example embodiments. It will be understood that some of the actions and functionality described may be implemented at least in part by program instructions. These program instructions (computer code) may be provided to a processor of a device to produce a special purpose machine, such that the instructions, which execute via a processor of the device, implement the functions/acts specified.

It is worth noting that while specific elements are used in the figures, and a particular ordering of elements has been illustrated, these are non-limiting examples. In certain contexts, two or more elements may be combined, an element may be split into two or more elements, or certain elements may be re-ordered or re-organized as appropriate, as the explicit illustrated examples are used only for descriptive purposes and are not to be construed as limiting.

As used herein, the singular “a” and “an” may be construed as including the plural “one or more” unless clearly indicated otherwise.

For any numbers, measurements, or dimensions, the stated numbers, measurements, or dimensions are to be understood to include approximately the value stated, which is indicated by use of the term “about,” for example including rounding of the last significant digit, unless explicitly explained otherwise, such as by using an exact value.

This disclosure has been presented for purposes of illustration and description but is not intended to be exhaustive or limiting. Many modifications and variations will be apparent to those of ordinary skill in the art. The example embodiments were chosen and described in order to explain principles and practical application, and to enable others of ordinary skill in the art to understand the disclosure for various embodiments with various modifications as are suited to the particular use contemplated.

Thus, although illustrative example embodiments have been described herein with reference to the accompanying figures, it is to be understood that this description is not limiting and that various other changes and modifications may be affected therein by one skilled in the art without departing from the scope or spirit of the disclosure.

What is claimed is:

1. An evaporator for cooling a server rack enclosure, comprising:
an evaporator housing comprising:
a first surface having a first end that includes a warm air inlet that conducts warm air from inside a server rack enclosure and second end that includes a cool air outlet that returns cooled air to the server rack enclosure;
evaporator coils positioned between the warm air inlet and the cool air outlet that cool the warm air from the inside of the server rack enclosure; and
an airflow generating unit that provides airflow between the warm air inlet and the cool air outlet, the airflow transiting about the evaporator coils;
the evaporator coils including tubing positioned in a connection port of the evaporator housing;
the tubing being configured to attach to a remote condenser unit.

2. The evaporator of claim 1, wherein the evaporator housing is mountable within a rack of the server rack enclosure.

3. The evaporator of claim 2, wherein the evaporator housing is repositionable within the rack.

4. The evaporator of claim 1, wherein the evaporator housing comprises a second surface, opposite the first surface, and wherein the second surface comprises a first end that includes a second warm air inlet and second end that includes a second cool air outlet.

5. The evaporator of claim 4, comprising a plate that attaches to one or more of the first surface and the second surface.

6. The evaporator of claim 1, wherein the evaporator housing is about 10 inches in height, about 17 inches in width, and about 40 inches in depth.

7. The evaporator of claim 1, wherein the evaporator housing is about 14 inches in height, about 17 inches in width, and about 45 inches in depth.

8. The evaporator of claim 1, wherein the evaporator housing is about 15 inches in height, about 17 inches in width, and about 45 inches in depth.

9. The evaporator of claim 1, wherein the evaporator housing fits entirely within the server rack enclosure for closed-loop cooling of the server rack enclosure.

10. The evaporator of claim 1, wherein evaporator housing comprises one or more side air inlets and one or more side air outlets.

11. A system for cooling a server rack enclosure, comprising:
a housing comprising:
a first surface having a first end that includes a warm air inlet that conducts warm air from inside a server rack enclosure and second end that includes a cool air outlet that returns cooled air to the server rack enclosure;
evaporator coils positioned between the warm air inlet and the cool air outlet that cool the warm air from the inside of the server rack enclosure; and
an airflow generating unit that provides airflow between the warm air inlet and the cool air outlet, the airflow transiting about the evaporator coils; and
a mounting mechanism for mounting the housing at a position within the server rack enclosure selected from the group consisting of a bottom mount position, a middle mount position, and a top mount position;
wherein the mounting mechanism comprises a bracket that reversibly attaches to server rails within the server rack enclosure housing.

12. The system of claim 11, wherein the housing comprises an evaporator housing having tubing for connection to tubing of a remote condenser.

13. The system of claim 11, wherein the housing comprises:
a second surface having a second warm air inlet and a second cool air outlet; and
two side surfaces, each of the two side surfaces having one or more side air inlets and one or more side air outlets.

14. A system comprising:
a server rack enclosure;
a server rack comprising a plurality of rails; and
an evaporator housing comprising:
a first surface having a first end that includes a warm air inlet that conducts warm air from inside a server rack enclosure and second end that includes a cool air outlet that returns cooled air to the server rack enclosure; and
evaporator coils positioned between the warm air inlet and the cool air outlet that cool the warm air from the inside of the server rack enclosure;
an airflow generating unit that provides airflow between the warm air inlet and the cool air outlet, the airflow transiting about the evaporator coils;
the evaporator coils including tubing positioned in a connection port of the evaporator housing;
the tubing being configured to attach to a remote condenser unit.

15. The system of claim 14, comprising a plate that attaches to the first surface of the evaporator housing.

16. The system of claim 14, comprising a mounting mechanism for mounting the evaporator housing at a position within the server rack enclosure selected from the group consisting of a bottom mount position, a middle mount position, and a top mount position;

17. The system of claim 16, wherein the mounting mechanism comprises a bracket that reversibly attaches to server rails within the server rack enclosure housing.

18. The system of claim 14, wherein the evaporator housing comprises a second surface, opposite the first surface, and wherein the second surface comprises a first end that includes a second warm air inlet and second end that includes a second cool air outlet.

19. The system of claim 18, wherein the evaporator housing comprises two side surfaces, each of the two side surfaces having one or more side air inlets and one or more side air outlets.

20. The system of claim 14, comprising the remote condenser unit configured to attach to the tubing of the evaporator housing.
